(19) United States
(12) Patent Application Publication
(10) Pub. No.: US 2007/0082438 A1
(43) Pub. Date: Apr. 12, 2007

(54) Thin film transistor and method for fabrication of an electronic device

(75) Inventors: Shunpu Li, Cambridge (GB); Christopher Newsome, Cambridge (GB); David Russell, Cambridge (GB); Thomas Kugler, Cambridge (GB)

Correspondence Address: OLIFF & BERRIDGE, PLC, P.O. BOX 19928, ALEXANDRIA, VA, 22320, US

(73) Assignee: SEIKO EPSON CORPORATION, TOKYO (JP)

(21) Appl. No.: 11/540,729

(22) Filed: Oct. 2, 2006

(30) Foreign Application Priority Data
Oct. 6, 2005 (GB) 0520350.0

(51) Int. Cl. H01L 21/8238

(52) U.S. Cl. 438/206

(57) ABSTRACT

A method for fabricating an electronic device is disclosed, the method comprising depositing a first layer of insulator over a substrate, depositing a first layer portion over the insulator using a printing technique, and removing a portion of the insulator using a photo-exposure technique or an etching technique, using the first layer portion as a mask. A vertical short channel thin film transistor is also disclosed, the transistor comprising a substrate, a first electrode formed over the substrate, a first layer of insulator formed over a portion of the first electrode, a second electrode formed over the first layer of insulator, a semiconductor layer forming a channel between the first and second electrodes, a dielectric layer formed over the semiconductor layer, and a gate electrode formed over the dielectric layer, wherein the gate electrode spans at least a part of the channel between the first and second electrodes.

The invention relates to a method for fabricating electronic devices including, but not limited to, thin film transistors. The invention also relates to a thin film transistor.

### BACKGROUND OF THE INVENTION

A significant problem encountered in the development of advanced electronic devices is the lack of available simple and low-cost high resolution patterning techniques. Conventional optical lithography is one technique that has been extensively used for device fabrication. While photolithography allows for high resolution patterning, the alignment of the photo-mask to previously defined structures on the substrate can be difficult and can dramatically increase the production costs of a device. Although some other techniques, such as micro-embossing, nano-imprinting, micro-cutting and near-field optical techniques, are promising for high resolution patterning, there are still challenges for mass production of electronic devices. For example, it would be desirable to allow roll-to-roll processes, which are highly efficient, to be used more extensively in device manufacture. A very promising and highly productive method of device fabrication uses ink-jet technology, wherein the functional materials are deposited by ink-jet printing to form devices. However the main limitation of using ink-jet printing is its resolution, which is currently about 50 μm. This resolution is problematic in the manufacture of some electronic devices. For example, it is known that the electronic current density (an important work parameter) of a thin film transistor (TFT), is inversely proportional to the channel length between the source and drain electrodes. For many applications, the channel length of a TFT should ideally be less than 1 μm.

There exist several techniques, such as optical lithography, nano-imprinting and soft-contact printing, which can be used to fabricate electronic circuits with high resolutions. However, usually these techniques can only be used to produce one layer of the device, for example the source-drain electrode layer or the gate electrode layer in the case of TFTs. The fabrication of subsequent structured layers of the device will then require alignment to the aforementioned layer. Such an alignment procedure is typically used in conventional photolithography processes. Especially in the case of large area, flexible substrates, such an alignment process can present major difficulties due to the occurrence of warping, thermal expansion or shrinking of the substrate. Furthermore, in the case of a roll-to-roll fabrication environment, non-uniform distortions due to the necessary tensions applied to the substrate during transfer cause alignment difficulties. Ink-jet printing techniques are a very promising way to produce electronic devices using roll-to-roll processes. However, as mentioned above, the resolution of ink-jet printing is very limited at the present time (typically a few tens of micrometers).

It is desired to manufacture TFTs having a channel length of a few microns or less in order to gain sufficient performance in terms of the electronic current density and to provide a sufficiently high cut-off frequency. It is also desired to manufacture such TFTs using roll-to-roll processes. Combining ink-jet printing with other high resolution fabrication technologies is one possible method for producing TFTs and other circuits. For example, in one technique a photo-lithographically defined bank structure is used to confine ink-jet printed droplets during manufacture of a TFT to reduce the resulting channel length of the TFT. However, such a method can only be used to fabricate a structure having a resolution of several microns. To obtain a sufficiently high electronic current density it is preferable for the TFT channel length to be sub-micrometer.

Thus a major problem in connection with the fabrication of TFTs and circuits is that devices with a sufficiently high resolution cannot be manufactured efficiently using roll-to-roll processes or on large area, flexible substrates, where conventional alignment-based techniques are difficult to use. Existing ink-jet printing techniques do not have a high enough resolution to be used to solve this problem.

### SUMMARY OF THE INVENTION

The present invention relates to a combination of a printing technique and a self-aligned photo-exposure or etching process which allows fabrication of devices having a sub-micron resolution in roll-to-roll processes.

In a first aspect of the invention, there is provided a method for fabricating an electronic device, comprising: depositing a first layer of insulator over a substrate; depositing a first layer portion over the insulator using a printing technique; and removing a portion of the insulator using a photo-exposure technique or an etching technique, using the first layer portion as a mask.

The invention provides a method for fabricating commercial electronic devices and circuits. The method according to the invention combines printing and self-aligned photo-exposure or etching to exploit the advantages of both techniques. In the method according to the invention the first layer portion has a relatively low resolution due to the use of a printing technique, but the adverse effects of this low resolution on the properties of the resulting device are minimised by the subsequent use of the first layer portion as a mask. As a result, the invention allows high resolution electronics to be fabricated on a larger scale than has previously been possible, using roll-to-roll processes.

Preferably, the method further comprises depositing a second layer portion over the substrate before depositing the first layer of insulator. Suitably, the step of depositing the second layer portion comprises depositing a transparent material. Preferably, the first layer portion is offset relative to the second layer portion.

Suitably, the step of depositing the first layer portion comprises depositing a first electrode and the step of depositing the second layer portion comprises depositing a second electrode. Preferably, the method further comprises: depositing a semiconductor layer over the first electrode, the insulator and the second electrode. More preferably, the method further comprises: depositing a dielectric layer over the semiconductor layer. Suitably, the method further comprises: depositing a third electrode over the dielectric layer, the third electrode spanning at least part of the gap between the first and second electrodes.

Preferably, the third electrode is deposited by ink-jet printing. More preferably, the step of depositing the third electrode comprises depositing poly(3,4-ethylenedioxythiophene)-polystyrenesulphonic acid (PEDOT-PSS) or a metal colloidal suspension. Alternatively, the step of depositing the third electrode comprises depositing a colloidal suspension of silver or gold.

Preferably the method further comprises depositing a second layer of insulator over the substrate before depositing the second layer portion, wherein the step of removing a portion of the insulator includes removing a part of the second layer portion. Conveniently, the second layer portion is deposited by ink-jet printing. Suitably, the first layer portion is deposited by ink-jet printing.

Conveniently, the first layer of insulator is deposited by ink-jet printing. Alternatively, the first layer of insulator is formed by spin coating.

Suitably, the step of depositing the first layer of insulator comprises depositing a photo-resist material and the step of removing a portion of the insulator comprises a photo-exposure technique. Preferably the step of depositing the first layer of insulator comprises depositing one of polymethylsiloxane, an AZ-series photoresist and an S-series photoresist. More preferably, the step of depositing the first layer of insulator comprises depositing AZ-5214E. Alternatively, the step of depositing the first layer of insulator comprises depositing S 1811 or S 1805.

Suitably, the step of removing a portion of the insulator comprises a plasma etching technique.

Preferably, the step of depositing the first layer portion comprises printing a silver or gold colloidal ink.

Suitably, the step of depositing the first layer of insulator comprises depositing a layer of insulator having a thickness of 1 μm or less.

Preferably, there is provided a method for fabricating a thin film transistor comprising a method as described above.

According to a second aspect of the present invention there is provided a vertical short channel thin film transistor comprising: a substrate; a first electrode formed over the substrate; a first layer of insulator formed over a portion of the first electrode; a second electrode formed over the first layer of insulator; a semiconductor layer forming a channel between the first and second electrodes; a dielectric layer formed over the semiconductor layer; and a gate electrode formed over the dielectric layer, wherein the gate electrode spans at least a part of the channel between the first and second electrodes.

In the thin film transistor according to the invention, the first and second electrodes are separated by the thickness of the first layer of insulator. This structure allows a semiconductor channel to be formed between the electrodes across the thickness of the first insulator layer. As a result, the length of the channel can be controlled by controlling the thickness of the first layer of insulator during manufacture. Thus the structure according to the invention allows a transistor having a short channel to be fabricated using lower resolution fabrication techniques than can be used with a transistor structure in which source and drain electrodes are separated laterally across a layer of the device.

Preferably, the first electrode is transparent and the second electrode is opaque. Suitably, the first electrode is formed from silver or gold. Alternatively, the first electrode is formed from poly(3,4-ethylenedioxythiophene)-polystyrenesulphonic acid (PEDOT-PSS).

Preferably, the semiconductor layer comprises polyarylamine (PAA), a thiophene based polymer or a small molecule semiconductor. More preferably, the semiconductor layer comprises poly 3-hexylthiophene (P3HT) or poly(5,5′-bis(3-dodecyl-2-thienyl)-2,2′-bithiophene) (PQT-12). Alternatively, the semiconductor layer comprises pentacene or anthracene.

Preferably, the dielectric layer comprises one of poly(4-vinylphenol) (PVP), poly(4-methyl-1-pentene) (PMP) and benzocyclobutene (BcB).

Suitably, the gate electrode comprises poly(3,4-ethylenedioxythiophene)-polystyrenesulphonic acid (PEDOT-PSS).

Preferably, wherein the first layer of insulator comprises a photo-resist material. Alternatively, the first layer of insulator comprises poly(methyl methacrylate) (PMMA) or polymethylglutarimide (PMGI).

Preferably, the first layer of insulator has a thickness of 1 μm or less.

### BRIEF DESCRIPTION OF THE DRAWINGS

Embodiments of the present invention will now be described by way of further example only and with reference to the accompanying drawings, in which:

FIG. 1 shows a TFT fabrication process according to an embodiment of the invention using photo-exposure.

FIG. 2 shows a TFT fabrication process according to an alternative embodiment of the invention using photo-exposure.

FIG. 3 shows a TFT fabrication process according to an embodiment of the invention using plasma etching.

FIG. 4 shows the output characteristics of a vertical short channel TFT fabricated using a technique according to an embodiment of the invention.

### DETAILED DESCRIPTION

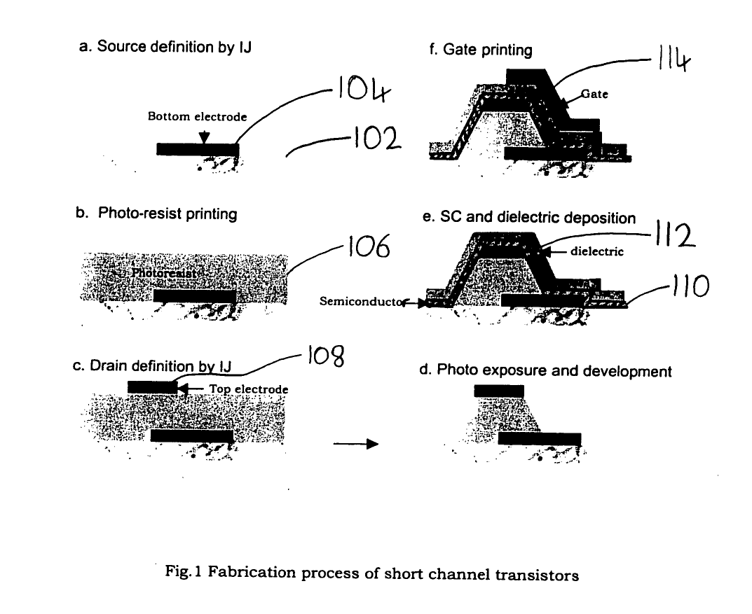

A TFT fabrication process according to a preferred embodiment of the invention is illustrated in FIG. 1. A source (or drain) electrode 104 and a layer of photo-resist 106 is printed on a substrate 102 (FIG. 1a, 1b). Afterwards a drain (or source) electrode 108 is printed on the photo-resist 106 (FIG. 1c). After each printing step a baking step is performed in order to remove solvent from the device and improve its conductivity. The baking conditions and the properties of the photo-resist 106 are selected to be compatible with the subsequent exposure and development process. The lateral dimension of the printed photo-resist layer 106 must be sufficient to isolate the source and drain electrodes 104, 108. The thickness of the photo-resist layer 106 corresponds to the vertical channel length of the fabricated TFT and should therefore be approximately 1 μm or less. In this embodiment the TFT is formed by self-aligned photo-exposure using the top electrode 108 as a mask. Hence the top electrode 108 must be opaque, and it is deposited in an offset position relative to the bottom electrode 104. After photo-exposure using the top electrode 108 as mask and subsequent development, a vertical short gap between the two electrodes 104, 108 is formed (FIG. 1d). A semiconductor layer 110 is then deposited over the structure produced and a dielectric layer 112 is deposited on the semiconductor layer 110 (FIG. 1e). Finally a gate electrode 114 is printed on the dielectric layer 112 to complete the TFT fabrication (FIG. 1f).

The following is a detailed example of a fabrication process according to the first embodiment of the invention, as shown in FIG. 1. A glass substrate was provided. A water-based silver colloidal ink was ink-jet printed onto the substrate to form a silver line constituting a bottom electrode. After annealing the structure at 160° C. for 30 min, a layer of photo-resist roughly 1 μm thick was spin coated on the sample. The photo-resist material used was one of polymethylsiloxane, AZ-5214E and S 1811. After drying the photo-resist film at 60° C. for 5 min, a silver line constituting a top electrode was ink-jet printed on the photo-resist. The printing resolution of the silver lines was about 50 μm, and the top silver line was off-set by 20 μm relative to the bottom silver line when printing was carried out. Subsequently, the sample was baked using conditions selected according to the demands of the following photo-resist exposure. For example, where the photo-resist used was AZ-5214E, the conditions for baking were a temperature of 100° C. and a duration of 4 min. For an S 1811 photo-resist the baking was performed at 90° C. for 30 min.

In the next step, the photo-resist was exposed using the top electrode as a mask. After development, the sample was baked again to improve the mechanical properties of the top silver electrode. The conditions for baking in this step again depend on the photo-resist material. The baking temperature should be less than the melting temperature of the photo-resist used. For an AZ type photo-resist a temperature of up to around 120° C. can be used to anneal the silver electrodes, while for a polymethylsiloxane photo-resist a much higher temperature can be used, up to around 300° C. The top and bottom electrodes constitute the source and drain electrodes of the completed transistor.

After the silver source and drain electrodes were formed, a layer of an organic semiconductor was deposited. As the organic semiconductor layer, polyarylamine (PAA), poly 3-hexylthiophene (P3HT) and other polymers can be deposited by spin-coating. Alternatively, Pentacene, Anthracene and other small semiconductor molecules can be deposited by thermal evaporation. The material used for the semiconductor layer must be chemically compatible with the photo-resist. A dielectric layer was then deposited on the organic semiconductor layer. Dielectric materials such as poly(4-vinylphenol) and poly(4-methyl-1-pentene) (PMP) can be deposited by spin-coating to form the dielectric layer. The typical thicknesses of the semiconductor layer and the dielectric layer are 20-100 nm and 400-2000 nm, respectively. Finally a gate electrode consisting of poly(3,4-ethylenedioxythiophene)-polystyrenesulphonic acid (PEDOT-PSS) was printed on the dielectric layer.

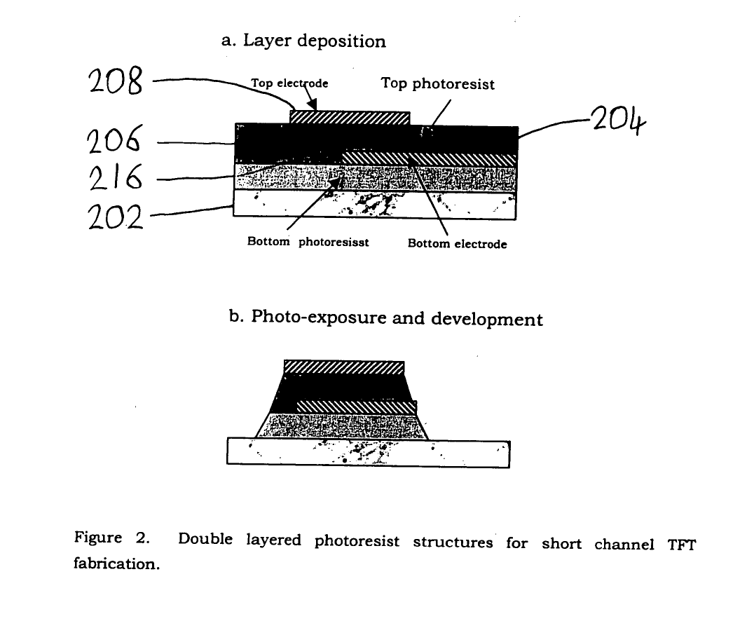

In a second embodiment, to allow a thicker dielectric layer to be formed and to provide a very short channel, a double layer of photo-resist is used as shown in FIG. 2. The use of a double layer of photo-resist improves the positioning of the gate electrode relative to the source and drain electrodes 204, 208. In the manufacturing process illustrated in FIG. 2a, a bottom layer of photo-resist 216, a bottom electrode 204, a top layer of photo-resist 206 and a top electrode 208 are deposited sequentially on a substrate 202. As in the first embodiment, the top electrode 208 must be optically non-transparent as it acts as a self-aligned mask. Furthermore, in this second embodiment the bottom electrode 204 should be transparent in order to expose the bottom layer of photo-resist 216 during photo-exposure.

After steps of baking, photo-exposure, and development have been performed, the obtained source-drain structure is that illustrated in FIG. 2b. In this structure fabrication process, the combination of photo-resist materials used for the top and bottom layers of photo-resist 206, 216 is crucial. It has been found to be advantageous to select different types of photo-resist for the top and bottom layers 206, 216 and to use a multi-step photo-exposure and development process. However, the same photo-resist may be used for both top and bottom layers 206, 216 and a single-step photo-exposure and development process may be used. Where the bottom electrode 204 is ink-jet printed, lift-off is not a problem as the film is not required to be continuous. Using this structure having a double layer of photo-resist facilitates depositing the gate electrode so as to cover the gap between the source and drain electrodes.

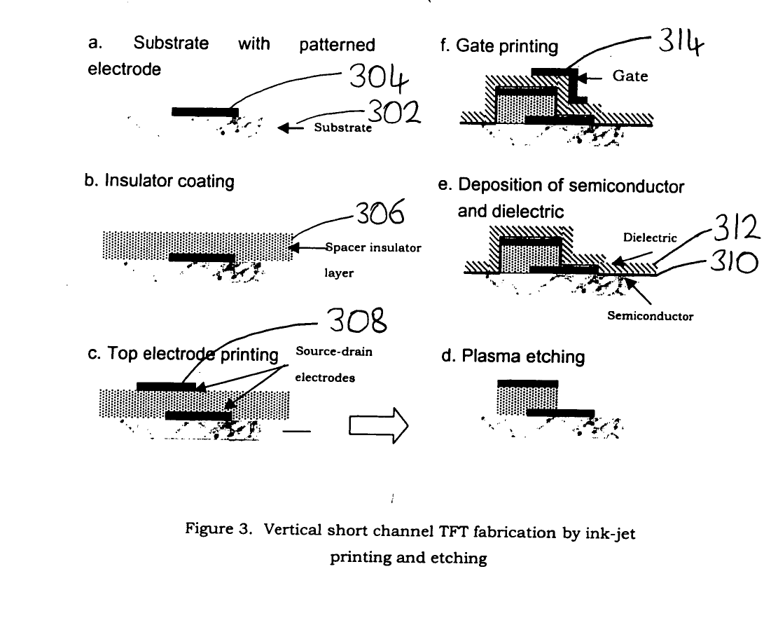

Techniques other than photo-exposure can also be combined with ink-jet printing to fabricate a short channel transistor using the same self-aligned principle, as illustrated in FIG. 3, which shows a third embodiment of the invention using plasma etching. Firstly, a bottom electrode 304 is deposited on a substrate 302 (FIG. 3a). A spacer insulator layer 306 is then spin-coated on the structure (FIG. 3b), and another electrode 308 which has a predetermined offset relative to the bottom electrode 304 is formed on the insulator layer 306 by ink-jet printing (FIG. 3c). Subsequently, etching is performed through the entire thickness of the insulator layer 306 by using the top electrode 308 as a mask (FIG. 3d). A semiconductor layer 310 is deposited over the resulting structure and a dielectric layer 312 is deposited on the semiconductor layer 310 (FIG. 3e). Finally a gate electrode 314 is printed on the dielectric layer 312 (FIG. 3f).

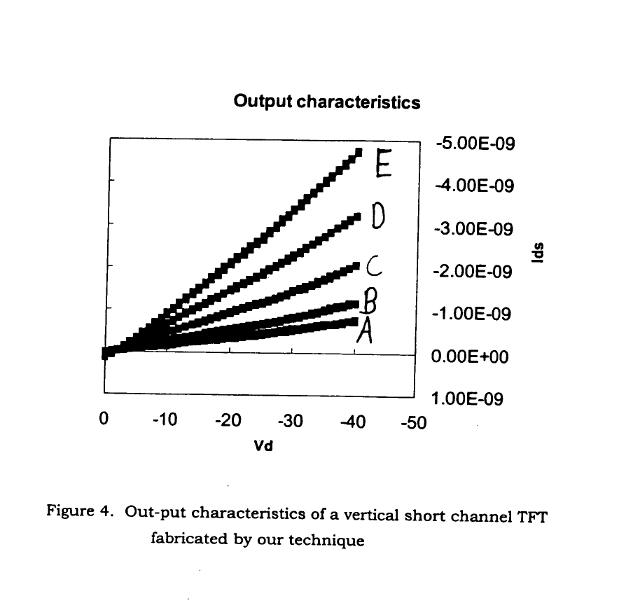

The following is a detailed example of a process according to the third embodiment of the invention, as shown in FIG. 3. The TFT fabrication was performed using a glass substrate on which a patterned gold electrode was formed by photolithography. A 1 micron thick layer of PMMA (poly(methyl methacrylate)) was spun onto the substrate, following which baking was performed at 140° C. for 5 min. Then a top electrode was printed on the PMMA layer, the top electrode consisting of a 200 nm thick layer of PEDOT-PSS (PEDOT: Poly(3,4-ethylene-dioxythiophene); PSS: Poly(styrenesulfonic acid)). Oxygen plasma etching was then performed to etch through the entire thickness of a portion of the PMMA layer, using the top PEDOT-PSS electrode as a mask. After the etching step, a 50 nm thick PAA (Polyarylamine) or polythiophene semiconductor layer was spin-coated over the resulting structure and a 1 μm thick PVP (Poly(4-vinylphenol)) dielectric layer was spin-coated onto the semiconductor layer. After each coating step the sample was baked at 60° C. for 30 min. A 100 nm thick layer of PEDOT-PSS was ink-jet printed onto the dielectric layer to define the gate electrode. FIG. 4 shows the output characteristics of the fabricated transistor. Curves A to E represent the relationships between the drain voltage Vd (V) and the drain-source current Ids (A) of the transistor at different gate voltages Vg. The gate voltage Vg for each curve is shown in Table 1 below.

TABLE 1

| | Curve | | | | |
|---|---|---|---|---|---|
| | A | B | C | D | E |
| Vg (V) | 0 | 10 | 20 | 30 | 40 |

The hard saturation behaviour of the fabricated transistor shows a strong short channel effect.

It should be noted that although the above examples relate to the fabrication of TFTs, the manufacturing method of the invention is not limited thereto and can be used in fabricating any electronic component or circuit.

The structure featuring a double layer of insulating material according to the second embodiment can also be applied to the third embodiment involving plasma etching. In this modification a second spacer insulator layer is deposited between the substrate 302 and the bottom electrode 304, before the step of forming the bottom electrode 304. This modification provides the same advantages as the second embodiment, i.e. it facilitates depositing the gate electrode so as to cover the gap between the source electrode and the drain electrode.

The examples of suitable techniques and materials given below can be applied to all of the above embodiments.

Alternative deposition techniques for the spacer insulator, semiconductor and dielectric layers include doctor blading, printing (e.g. ink-jet printing, screen printing, offset printing, flexo printing and pad printing), thermal evaporation, sputtering, chemical vapour deposition, dip- and spray-coating and electroless plating.

Alternative ways of creating the bottom electrode include ink-jet printing, photo-lithography, nano-imprinting, soft-contact printing, off-set printing and screen printing. As the alignment between the top electrode and the bottom electrode has a large tolerance in the fabrication techniques described above, printing techniques other than ink-jet printing, such as screen printing and soft-contact printing, can also be used.

Alternative materials for the electrodes include conductive polymers and both organic and inorganic colloidal suspensions. Alternative materials for the semiconductor layers include polymer and organic small molecular materials. Inorganic colloids, nanowire suspensions and organic-organic, organic-inorganic and inorganic-inorganic material compositions may all be used for the semiconductor layers.

Alternative materials for the spacer insulator and dielectric layers include inorganic, organic, organic-organic, organic-inorganic and inorganic-inorganic material compositions. The substrates used can be both rigid and flexible and can be formed from materials including glass, polymer and paper.

The aforegoing description has been given by way of example only and it will be appreciated by a person skilled in the art that modifications can be made without departing from the scope of the present invention.

1. A method for fabricating an electronic device, comprising:
depositing a first layer of insulator over a substrate;
depositing a first layer portion over the insulator using a printing technique; and
removing a portion of the insulator using a photo-exposure technique or an etching technique, using the first layer portion as a mask.

2. The method according to claim 1, further comprising depositing a second layer portion over the substrate before depositing the first layer of insulator.

3. The method according to claim 2, wherein the step of depositing the second layer portion comprises depositing a transparent material.

4. The method according to claim 2, wherein the first layer portion is offset relative to the second layer portion.

5. The method according to claim 2, wherein the step of depositing the second layer portion comprises depositing a first electrode and the step of depositing the first layer portion comprises depositing a second electrode.

6. The method according to claim 5, further comprising:
depositing a semiconductor layer over the first electrode, the insulator and the second electrode.

7. The method according to claim 6, further comprising:
depositing a dielectric layer over the semiconductor layer.

8. The method according to claim 7, further comprising:
depositing a third electrode over the dielectric layer, the third electrode spanning at least part of the gap between the first and second electrodes.

9. The method according to claim 8, wherein the third electrode is deposited by ink-jet printing.

10. The method according to claim 8, wherein the step of depositing the third electrode comprises depositing poly(3,4-ethylenedioxythiophene)-polystyrenesulphonic acid (PEDOT-PSS) or a metal colloidal suspension.

11. The method according to claim 9, wherein the step of depositing the third electrode comprises depositing a colloidal suspension of silver or gold.

12. The method according to claim 2, further comprising depositing a second layer of insulator over the substrate before depositing the second layer portion, wherein the step of removing a portion of the insulator includes removing a part of the second layer portion.

13. The method according to claim 2, wherein the second layer portion is deposited by ink-jet printing.

14. The method according to claim 1, wherein the first layer portion is deposited by ink-jet printing.

15. The method according to claim 1, wherein the first layer of insulator is deposited by ink-jet printing.

16. The method according to claim 1, wherein the first layer of insulator is formed by spin coating.

17. The method according to claim 1, wherein the step of depositing the first layer of insulator comprises depositing a photo-resist material and the step of removing a portion of the insulator comprises a photo-exposure technique.

18. The method according to claim 17, wherein the step of depositing the first layer of insulator comprises depositing one of polymethylsiloxane, an AZ-series photoresist and an S-series photoresist.

19. The method according to claim 18, wherein the step of depositing the first layer of insulator comprises depositing AZ-5214E.

20. The method according to claim 18, wherein the step of depositing the first layer of insulator comprises depositing S 1811 or S 1805.

21. The method according to claim 1, wherein the step of removing a portion of the insulator comprises a plasma etching technique.

22. The method according to claim 1, wherein the step of depositing the first layer portion comprises printing a silver or gold colloidal ink.

23. The method according to claim 1, wherein the step of depositing the first layer of insulator comprises depositing a layer of insulator having a thickness of 1 μm or less.

24. A method for fabricating a thin film transistor comprising the method according to claim 1.

25. A vertical short channel thin film transistor comprising:
a substrate;
a first electrode formed over the substrate;
a first layer of insulator formed over a portion of the first electrode;
a second electrode formed over the first layer of insulator;
a semiconductor layer forming a channel between the first and second electrodes;
a dielectric layer formed over the semiconductor layer; and
a gate electrode formed over the dielectric layer, wherein the gate electrode spans at least a part of the channel between the first and second electrodes.

26. The transistor according to claim 25, wherein the first electrode is transparent and the second electrode is opaque.

27. The transistor according to claim 25, wherein the first electrode is formed from silver or gold.

28. The transistor according to claim 25, wherein the first electrode is formed from poly(3,4-ethylenedioxythiophene)-polystyrenesulphonic acid (PEDOT-PSS).

29. The transistor according to claim 25, wherein the semiconductor layer comprises polyarylamine (PAA), a thiophene based polymer or a small molecule semiconductor.

30. The transistor according to claim 29, wherein the semiconductor layer comprises poly 3-hexylthiophene (P3HT) or poly(5,5′-bis(3-dodecyl-2-thienyl)-2,2′-bithiophene) (PQT-12).

31. The transistor according to claim 29, wherein the semiconductor layer comprises pentacene or anthracene.

32. The transistor according to claim 25, wherein the dielectric layer comprises one of poly(4-vinylphenol) (PVP), poly(4-methyl-1-pentene) (PMP) and benzocyclobutene (BcB).

33. The transistor according to claim 25, wherein the gate electrode comprises poly(3,4-ethylenedioxythiophene)-polystyrenesulphonic acid (PEDOT-PSS).

34. The transistor according to claim 25, wherein the first layer of insulator comprises a photo-resist material.

35. The transistor according to claim 25, wherein the first layer of insulator comprises poly(methyl methacrylate) (PMMA) or polymethylglutarimide (PMGI).

36. The transistor according to claim 25, wherein the first layer of insulator has a thickness of 1 μm or less.
